(19) United States
(12) Patent Application Publication
(10) Pub. No.: US 2024/0222225 A1
(43) Pub. Date: Jul. 4, 2024

(54) Liquid Immersion-Cooled Power Module

(71) Applicants: Hyundai Motor Company, Seoul (KR); Kia Corporation, Seoul (KR)

(72) Inventors: Suk Hyun Lim, Hwaseong-si (KR); Hyun Koo Lee, Seoul (KR); Sang Hun Lee, Hwaseong-si (KR); Se Heun Kwon, Incheon (KR); Ki Young Jang, Incheon (KR); Jun Hee Park, Hwaseong-si (KR)

(21) Appl. No.: 18/347,313

(22) Filed: Jul. 5, 2023

(30) Foreign Application Priority Data
Dec. 29, 2022 (KR) 10-2022-0188364

(51) Int. Cl. H01L 23/473; H01L 23/00; H01L 25/07; H01L 25/18

(52) U.S. Cl. CPC H01L 23/473; H01L 24/37; H01L 24/40; H01L 25/072; H01L 25/18; H01L 2224/37013; H01L 2224/40137; H01L 2224/40175

(57) ABSTRACT

An embodiment liquid immersion-cooled power module includes an enclosure, an insulating liquid filling the enclosure, a substrate disposed inside the enclosure, the substrate having a plurality of cooling fins in thermal contact with the insulating liquid, and a chip on the substrate inside the enclosure. Another embodiment liquid immersion-cooled power module further includes a connection body electrically connecting the plurality of substrates to each other.

### CROSS-REFERENCE TO RELATED APPLICATIONS

The present application claims the benefit of Korean Patent Application No. 10-2022-0188364, filed on Dec. 29, 2022, which application is hereby incorporated herein by reference.

### TECHNICAL FIELD

The present disclosure relates to a liquid immersion-cooled power module.

### BACKGROUND

A power conversion device (e.g., an inverter), one of the main components of hybrid and electric vehicles, is an essential part of eco-friendly vehicles, and many technologies related thereto are currently being developed. In particular, the development of power modules, which are the core of power conversion devices and account for most of the cost of such power conversion devices, is a major technology issue in the field of eco-friendly vehicles.

Key points of power module technology development are cost reduction and cooling performance improvement. Improving the cooling performance of a power module can lower the rated current of a chip being used and reduce the size of the chip, enabling cost reduction of the chip and stable operation of the power module.

Meanwhile, an insulating layer for electrical insulation is applied to a substrate of a power module, and as the insulating layer is added to the substrate, the manufacturing process becomes more complex and the weight increases while the cooling efficiency decreases.

The matters described as the background above are only for enhancing the understanding of the background of embodiments of the present disclosure and should not be taken as acknowledging that they correspond to the prior art already known to those of ordinary skill in the art.

### SUMMARY

The present disclosure relates to a liquid immersion-cooled power module. Particular embodiments relate to a liquid immersion-cooled power module in which a substrate is insulated by an insulating liquid filled inside an enclosure and one or more chips are cooled using the insulating liquid.

Accordingly, embodiments of the present disclosure have been made keeping in mind problems occurring in the related art, and embodiments of the present disclosure provide a liquid immersion-cooled power module in which a substrate is insulated by an insulating liquid filled inside an enclosure and the insulating liquid directly contacts one or more chips, which are a heating element, to cool the chips, thereby simplifying the structure and improving insulation performance and cooling efficiency compared to an indirect-cooled power module.

According to an embodiment of the present disclosure, there is provided a liquid immersion-cooled power module including an enclosure filled with an insulating liquid therein and a substrate on which one or more chips are provided, impregnated inside the enclosure to be insulated by the insulating liquid, and configured to have a plurality of cooling fins exchanging heat with the insulating liquid.

The substrate may be a metal plate made of a metal material.

A support body connected to the substrate may be provided inside the enclosure, so that the substrate may be fixed inside the enclosure by the support body.

The plurality of cooling fins may be formed on either one of a first side and a second side of the substrate or on both the first side and the second side of the substrate.

The enclosure may be provided with an inlet and an outlet connecting from an outside to an inside so that the insulating liquid is circulated.

The inlet and the outlet may be arranged on a straight line, and the substrate may be positioned on the straight line crossing the inlet and the outlet inside the enclosure.

The inlet and the outlet of the enclosure may be connected to a flow path through which the insulating liquid flows, and a pump may be provided in the flow path so that the insulating liquid flows in through the inlet and then is discharged through the outlet.

The power module may further include a cooler provided inside or outside the enclosure to cool the insulating liquid.

The substrate may be vertically disposed in the enclosure, and the cooler may be located on an outer top or an inner top of the enclosure.

The substrate may be provided in plurality, and the plurality of substrates may be electrically connected to each other through a connection body.

The connection body may be provided with a plurality of protruding fins that exchange heat with the insulating liquid.

The connection body may be connected to the chips of each substrate, and the plurality of protruding fins may be formed at a portion of the connection body connected with the chips.

In the power module having the structure as described above, since a substrate is insulated by an insulating liquid filled inside an enclosure and the insulating liquid directly contacts one or more chips, which are a heating element, to cool the chips, it is possible to simplify the structure and improve insulation performance and cooling efficiency compared to an indirect-cooled power module.

In addition, since a plurality of cooling fins are formed on the substrate to increase the contact area with the insulating liquid, the efficiency of heat exchange with the insulating liquid is improved, thereby improving the cooling efficiency of the chips and the substrate.

Furthermore, compared to the conventional dual side indirectly cooled power module, the number of parts is significantly reduced, which reduces the manufacturing cost, and cracks or damage caused by the difference in thermal expansion coefficient between joined parts is prevented, thereby significantly improving the lifespan or reliability of the power module.

### BRIEF DESCRIPTION OF THE DRAWINGS

The above and other objectives, features, and other advantages of embodiments of the present disclosure will be more clearly understood from the following detailed description when taken in conjunction with the accompanying drawings, in which:

FIG. 1 is a view showing a liquid immersion-cooled power module according to an embodiment of the present disclosure;

FIG. 2 is a perspective view of the power module according to the embodiment of the present disclosure shown in FIG. 1;

FIG. 3 is a view showing the inside of an enclosure of the power module according to the embodiment of the present disclosure shown in FIG. 1;

FIG. 4 is a plan view showing the inside of the enclosure of the power module according to the embodiment of the present disclosure shown in FIG. 1;

FIG. 5 is a view showing a cooling fin or protruding fin according to embodiments of the present disclosure; and

FIG. 6 is a view showing a liquid immersion-cooled power module according to another embodiment of the present disclosure.

### DETAILED DESCRIPTION OF ILLUSTRATIVE EMBODIMENTS

Hereinafter, embodiments disclosed in the present specification will be described in detail with reference to the accompanying drawings, with the same or similar elements being assigned the same reference numerals throughout the drawings, and overlapping descriptions thereof will be omitted.

The expressions “module” and “part” for the elements used in the following description are given or interchanged in consideration of only the ease of writing the specification and do not have distinct meanings or roles by themselves.

In describing the embodiments disclosed in this specification, if it is determined that detailed descriptions of related known technologies may obscure the gist of the embodiments disclosed in this specification, the detailed description thereof will be omitted. In addition, it should be understood that the accompanying drawings are only for easy understanding of the embodiments disclosed in the present specification, and the technical idea disclosed in the present specification is not limited by the accompanying drawings, and the disclosure covers all changes, equivalents, and substitutes within the spirit and scope of the present disclosure.

Terms including an ordinal number, such as first, second, etc., may be used to describe various elements, but the elements are not limited by the terms. These terms are used only for the purpose of distinguishing one element from another.

When an element is referred to as being “connected” to another element, it should be understood that the other element may be directly connected to the other element or other element(s) may exist in between. On the other hand, when it is said that a certain element is “directly connected” to another element, it should be understood that no other element is present between them.

The singular expression includes the plural expression unless the context clearly dictates otherwise.

In this specification, the terms “comprise”, “include”, or “have” are intended to indicate that there is a feature, number, step, action, element, part, or combination thereof described in the specification, and it is to be understood that embodiments of the present disclosure do not exclude the possibility of the presence or the addition of one or more other features, numbers, steps, actions, elements, parts, or combinations thereof.

Hereinafter, a liquid immersion-cooled power module according to preferred embodiments of the present disclosure will be described with reference to the accompanying drawings.

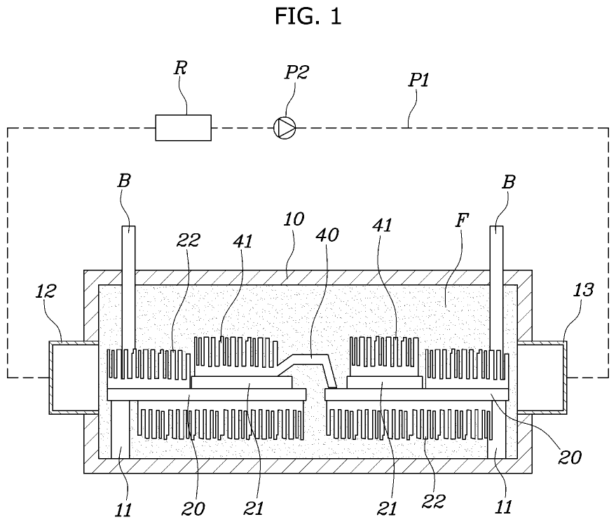

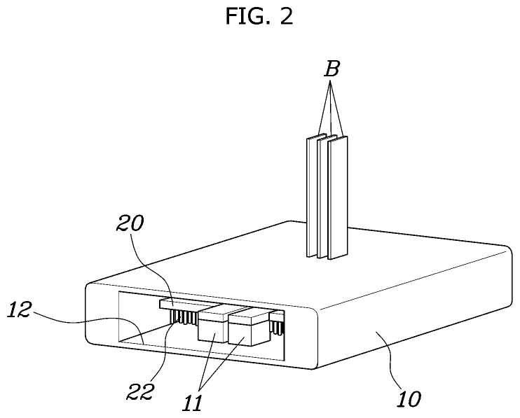

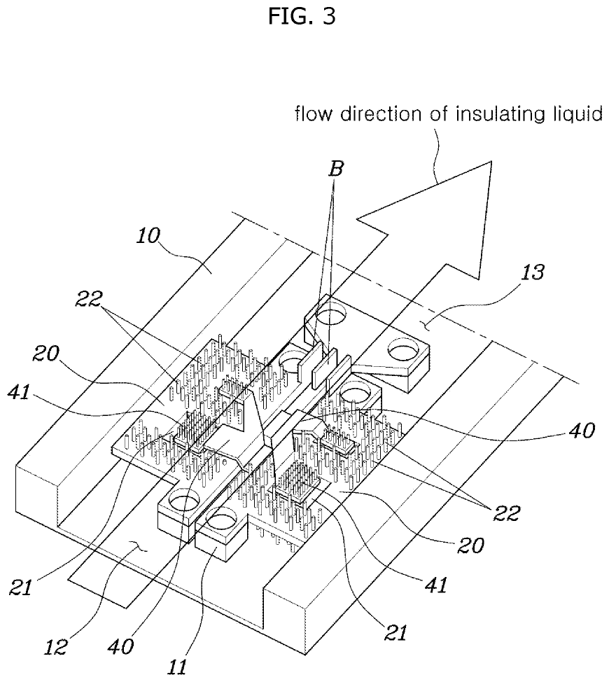

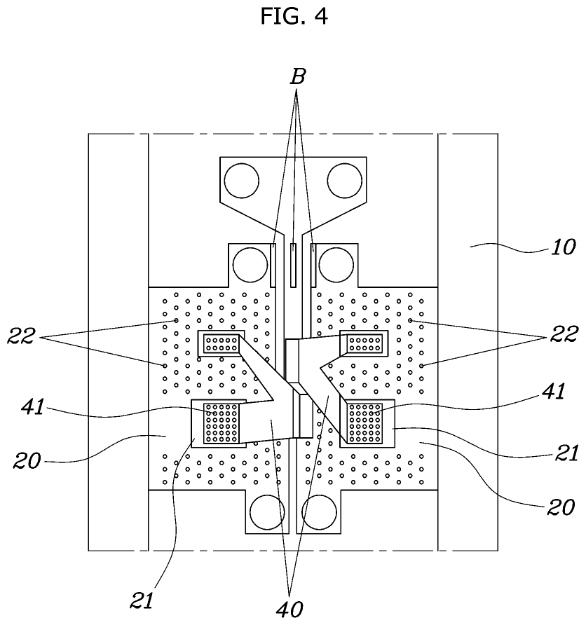

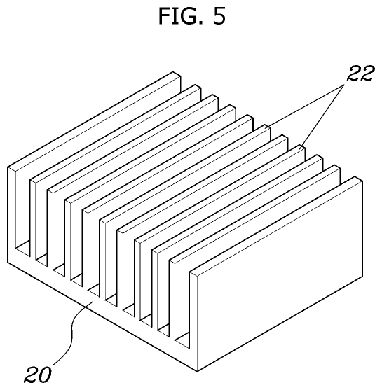

FIG. 1 is a view showing a liquid immersion-cooled power module according to an embodiment of the present disclosure; FIG. 2 is a perspective view of the power module according to the embodiment of the present disclosure shown in FIG. 1; FIG. 3 is a view showing the inside of an enclosure of the power module according to the embodiment of the present disclosure shown in FIG. 1; FIG. 4 is a plan view showing the inside of the enclosure of the power module according to the embodiment of the present disclosure shown in FIG. 1; and FIG. 5 is a view showing a cooling fin or protruding fin according to embodiments of the present disclosure.

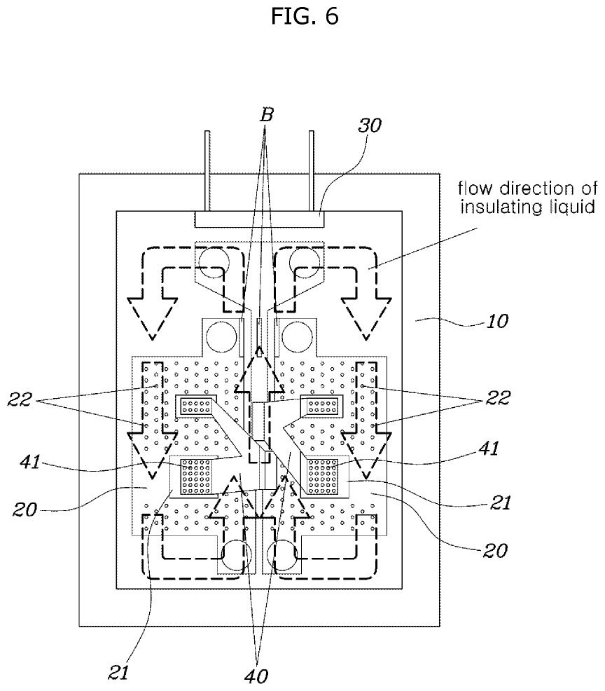

Meanwhile, FIG. 6 is a view showing a liquid immersion-cooled power module according to another embodiment of the present disclosure.

As shown in FIGS. 1 to 4, the power module according to embodiments of the present disclosure includes an enclosure 10 filled with an insulating liquid F therein and a substrate 20 on which one or more chips 21 are provided, impregnated inside the enclosure 10, and insulated by the insulating liquid F, the substrate 20 having a plurality of cooling fins 22 exchanging heat with the insulating liquid F.

In embodiments of the present disclosure, the enclosure 10 is filled with the insulating liquid F, and the substrate 20 is embedded in the enclosure 10 and impregnated with the insulating liquid F.

The enclosure 10 has an internal space so that the insulating liquid F is filled, and the watertight structure is maintained so that the insulating liquid F is blocked from leaking to the outside. The enclosure 10 may be made of various materials having insulating properties.

The chips 21 provided on the substrate 20 may be an element such as an insulated gate bipolar transistor (IGBT) or a diode for power conversion, and one or more chips 21 may be configured on the substrate 20.

The substrate 20 may be made of a metal material having high thermal conductivity so as to secure heat exchange efficiency and rigidity. Accordingly, the substrate 20 may include a metal plate.

The insulating liquid F is made to satisfy both thermal conductivity and insulation conditions and may include a liquid insulator used as a refrigerant.

Because of this, the substrate 20 has insulating properties even without an insulating layer due to the insulating liquid F filled inside the enclosure 10, and cooling efficiency is improved by applying a direct cooling method in which the insulating liquid F directly contacts the chips 21 and exchanges heat with the chips 21, which are a heating element, inside the enclosure 10.

The insulating liquid F may be configured to be circulated by natural convection according to the temperature change of the chips 21 in a state filled in the enclosure 10 or may be circulated inside and outside the enclosure 10 and managed at a temperature optimized for cooling the chips 21.

In embodiments of the present disclosure, a plurality of substrates 20 may be provided inside the enclosure 10 and may be disposed spaced apart from each other and electrically connected. The substrate 20 may be an electrically conductive substrate 20 obtained by removing an insulating layer from the DBC substrate 20, and an electrical circuit constituting a power module may be configured by electrically connecting individual substrates 20 with a connection body 40 to be described below. The connection body 40 may include clips, wire bonding, etc. for electrical connection.

Other various embodiments of the above-described enclosure 10 and substrate 20 are as follows.

As shown in FIGS. 1 to 3, a support body 11 connected to the substrate 20 is provided inside the enclosure 10, and the substrate 20 may be fixed inside the enclosure 10 by the support body 11.

At this time, the support body 11 may be made of the same insulating material as the enclosure 10 and may be integrally formed with the enclosure 10. In particular, the support body 11 is connected to the substrate 20 inside the enclosure 10 so that the substrate 20 is placed in the center of the enclosure 10.

Due to this, sufficient heat exchange may be achieved between the insulating liquid F filled in the enclosure 10 and all surface areas of the substrate 20 and the chips 21. In addition, durability and reliability of the substrate 20 are ensured as the position of the substrate 20 fixed in the inside of the enclosure 10 is fixed and stabilized by the support body 11.

Meanwhile, a plurality of cooling fins 22 may be formed on either one of one side and the other side of the substrate 20 or on both sides of the substrate 20.

That is, the cooling fins 22 may be formed on all areas of the substrate 20 except for the portion where the chips 21 are bonded and may be formed on either one of one side and the other side of the substrate 20 or on both sides of the substrate 20 according to the cooling specifications required by the substrate 20 and the chips 21.

Preferably, the cooling fins 22 are distributed on both sides of the substrate 20, so that the cooling performance of the substrate 20 may be ensured without increasing the size of the substrate 20.

In this way, the cooling fins 22 increase the contact surface with the insulating liquid F, so that heat conduction performance is ensured. The shape, size, and number of the cooling fins 22 may be determined according to the amount of current or heat generation of the chips 21, and the specifications of the cooling fins 22 may also be determined according to the cooling performance of the insulating liquid F.

In embodiments of the present disclosure, the cooling method of the substrate 20 and the chips 21 using the insulating liquid F may be applied in various embodiments.

According to an embodiment of the present disclosure, as shown in FIGS. 1 and 2, the enclosure 10 may be formed with an inlet 12 and an outlet 13 connecting from the outside to the inside so that the insulating liquid F is circulated.

The rest of the enclosure 10, except for the inlet 12 and the outlet 13, is formed in a watertight structure to block the outflow of the insulating liquid F to other parts except for the inlet 12 and the outlet 13.

In this way, as the inlet 12 is formed at one end of the enclosure 10 and the outlet 13 is formed at the other end, a circulation structure of the insulating liquid F may be formed in which the insulating liquid F introduced through the inlet 12 exchanges heat with the substrate 20 and the chips 21 and then is discharged through the outlet 13.

At this time, the inlet 12 and the outlet 13 of the enclosure 10 are connected to a flow path P1 through which the insulating liquid F flows, and a pump P2 is provided in the flow path P1 so that the insulating liquid F may flow in through the inlet 12 and then be discharged through the outlet 13.

In addition, a heat exchanger R is provided in the flow path P1 so that the temperature of the insulating liquid F may be managed through heat exchange between another cooling medium and the insulating liquid F. The heat exchanger R may include a cooler or a radiator for cooling the pump P2 and the insulating liquid F.

Accordingly, the circulation structure of the insulating liquid F is as follows. The pump P2 is driven to forcibly circulate the insulating liquid F along the flow path P1, the insulating liquid F flows into the inside of the enclosure 10 through the inlet 12 and exchanges heat with the substrate 20 and the chips 21 to cool the substrate 20 and the chips 21, and the insulating liquid F, the temperature of which has risen, may be discharged to the outside of the enclosure 10 through the outlet 13 of the enclosure 10 and cooled by the heat exchanger R.

Meanwhile, in the enclosure 10, the inlet 12 and the outlet 13 are arranged on a straight line, and the substrate 20 may be positioned on the straight line crossing the inlet 12 and the outlet 13 inside the enclosure 10.

Due to this, when the insulating liquid F introduced through the inlet 12 of the enclosure 10 is discharged through the outlet 13, a flow is formed that moves in one direction inside the enclosure 10. In addition, as the inlet 12 and the outlet 13 are arranged on the straight line in the enclosure 10, the flow of the liquid is stabilized, and the heat exchange efficiency between the insulating liquid F, the substrate 20, and the chips 21 may be improved.

Moreover, as the substrate 20 is positioned on the straight line where the inlet 12 and the outlet 13 face each other inside the enclosure 10, the insulating liquid F cooled from the outside and whose temperature is managed passes directly around the substrate 20 and the chips 21, so that the heat exchange efficiency may be further improved.

Furthermore, the cooling fins 22 formed on the substrate 20 may extend across the substrate 20 and extend in a direction in which the inlet 12 and the outlet 13 face each other.

As shown in FIG. 5, the cooling fins 22 may extend across the substrate 20 while having a flat shape to increase a contact area with the insulating liquid F. In addition, the cooling fins 22 may extend in the direction in which the inlet 12 and the outlet 13 face each other inside the enclosure 10, which is the flow direction of the insulating liquid F, so that the insulating liquid F passes smoothly between individual cooling fins 22 and the heat exchange between the cooling fins 22 and the insulating liquid F may be improved. Moreover, as the cooling fins 22 extend in a flat shape, interference with the flow of the insulating liquid F is minimized, resulting in smooth flow of the insulating liquid F.

The cooling fin 22 may extend in a curved shape as well as in a straight shape, and various shapes may be applied depending on the flowability of the insulating liquid F and the contact surface area.

Another embodiment of the present disclosure, as shown in FIG. 6, may further include a cooler 30 provided inside or outside the enclosure 10 to cool the insulating liquid F.

The cooler 30 may include a cooling channel or a cooling flow path, and as the cooling medium is applied as air or cooling water, the insulating liquid F may be cooled using an air-cooling method or a water-cooling method.

The cooler 30 may be provided inside or outside the enclosure 10 and indirectly cools the substrate 20 and the chips 21 by exchanging heat with the insulating liquid F through the circulation of a cooling medium. In the drawing, it is illustrated that the cooler 30 is disposed outside the enclosure 10.

In addition, a separate cooler or radiator is provided outside the cooler 30, so that the temperature of the cooling medium may be managed.

Accordingly, when heat is generated in the chips 21, the insulating liquid F inside the enclosure 10 generates a temperature difference within the insulating liquid F, resulting in a natural convection flow. In addition, as the cooler 30 exchanges heat with the insulating liquid F to generate a temperature difference within the insulating liquid F, the natural convection flow is accelerated, and cooling of the substrate 20 and the chips 21 by the insulating liquid F may be performed.

To be specific, the substrate 20 is vertically disposed in the enclosure 10, and the cooler 30 may be located on the outer top or the inner top of the enclosure 10.

The natural convective flow of the insulating liquid F inside the enclosure 10 is believed to be caused by the temperature difference. That is, a flow is created in which the insulating liquid F, whose temperature is raised by the heat dissipation of the chips 21, moves upward, and the insulating liquid F, which has a relatively low temperature, moves downward.

Therefore, as the substrate 20 according to embodiments of the present disclosure is vertically disposed inside the enclosure 10, cooling efficiency of the chips 21 by the insulating liquid may be improved by the natural convective flow of the insulating liquid F moving up and down along the substrate 20.

In addition, the cooler 30 may be located on the outer top or the inner top of the enclosure 10. That is, as the cooler 30 is located on the upper side of the enclosure 10, a flow may be created in which the insulating liquid F, which has been moved upward as the temperature thereof rises, is cooled by the cooler 30 and moves downward.

Thus, natural convection occurs by the temperature difference as the insulating liquid F is heated by the heat generated in the chips 21 and cooled by the cooler 30, and the substrate 20 and the chips 21 may be cooled by the flow of the insulating liquid F.

Meanwhile, the cooling fins 22 may be formed to extend across the substrate 20 and extend in a vertical direction.

In this way, the cooling fins 22 extend to cross the substrate 20 in a flat shape, so that the contact area with the insulating liquid F may be increased. In addition, as the cooling fins 22 extend in the vertical direction, which is the flow direction of the insulating liquid F by natural convection inside the enclosure 10, the insulating liquid F smoothly passes between the cooling fins 22, and heat exchange performance between the cooling fins 22 and the insulating liquid F may be improved. Moreover, as the cooling fins 22 extend in a flat shape, interference with the flow of the insulating liquid F is minimized, resulting in smooth flow of the insulating liquid F.

The cooling fin 22 may extend in a curved shape as well as in a straight shape, and various shapes may be applied depending on the flowability of the insulating liquid F and the contact surface area.

Meanwhile, a plurality of substrates 20 may be provided, and the plurality of substrates 20 may be electrically connected to each other through the connection body 40.

In the embodiment according to the present disclosure, although it is illustrated that two substrates 20 are configured and arranged in a horizontal direction, the number and arrangement of substrates 20 may be changed according to the specifications of the power module. Also, the chips 21 of the substrate 20 may be applied with different specifications.

Individual substrates 20 are electrically or physically connected by the connection body 40. That is, the chips 21 of the individual substrates 20 may be electrically connected by the connection body 40.

In addition, since the chips 21 need to be applied with control signals, current, and voltage from the outside, each substrate 20 has a bus bar B extending to penetrate the enclosure 10 to receive an electrical control signal from the outside. The bus bar B of each substrate 20 is formed to gather at a specific location in the enclosure 10, so that an electrical connection structure through the bus bar B may be simplified.

Meanwhile, a plurality of protruding fins 41 that exchange heat with the insulating liquid F may be formed on the connection body 40. In this way, since the plurality of protruding fins 41 are provided on the connection body 40, the connection body 40 may electrically connect the substrates 20, and the connection body 40 itself may be cooled through heat exchange with the insulating liquid F so as to improve the cooling performance of the chips 21.

That is, the connection body 40 electrically connects the individual substrates 20 to form a circuit as the chips 21 of the individual substrates 20 are connected, and as the contact area with the insulating liquid F is increased due to the protruding fins 41 of the connection body 40, the heat conduction performance is improved so that the connected chips 21 are cooled. As such, the connection body 40 not only enables circuit configuration through electrical connection between the chips 21, but it also improves the cooling performance of the chips 21 by cooling the connected chips 21 through heat exchange with the insulating liquid F.

The connection body 40 is connected to the chips 21 on the individual substrates 20, and the protruding fins 41 may be formed at a connection portion with the chips 21.

The connection body 40 may be connected in a form covering the upper surface of the chips 21, and the protruding fins 41 are formed at a portion connected to the chips 21 so that the cooling performance of the chips 21 is ensured. In this way, as the contact surface with the insulating liquid F is increased by the protruding fins 41, the heat conduction performance of the connection body 40 is ensured, and as the protruding fins 41 are formed at a portion connected to the chips 21, the cooling performance of the chips 21 is ensured.

The protruding fins 41 may extend across the surface of the connection body 40 and extend in the flow direction of the insulating liquid F.

In this way, the protruding fins 41 are extended to cross the surface of the connection body 40 in a flat shape, so that the contact area with the insulating liquid F may be increased. In addition, since the protruding fins 41 extend in the flow direction of the insulating liquid F, the insulating liquid F passes smoothly between the protruding fins 41, and heat exchange performance between the protruding fins 41 and the insulating liquid F may be improved.

The protruding fins 41 may extend in a curved shape as well as in a straight shape, and various shapes may be applied depending on the flowability of the insulating liquid F and the contact surface area.

The shape, size, and number of the protruding fins 41 may be determined according to the amount of current or heat generation of the chips 21, and the specifications of the protruding fins 41 may also be determined according to the cooling performance of the insulating liquid F.

In the power module having the structure as described above, since the substrate 20 is insulated by the insulating liquid F filled inside the enclosure 10 and the insulating liquid F directly contacts the chips 21, which are a heating element, to cool the chips 21, it is possible to simplify the structure and improve insulation performance and cooling efficiency compared to an indirect-cooled power module.

In addition, since the plurality of cooling fins 22 are formed on the substrate 20 to increase the contact area with the insulating liquid F, the efficiency of heat exchange with the insulating liquid F is improved, thereby improving the cooling efficiency of the chips 21 and the substrate 20.

Furthermore, compared to the conventional dual side indirectly cooled power module, the number of parts is significantly reduced, which reduces the manufacturing cost, and cracks or damage caused by the difference in thermal expansion coefficient between joined parts is prevented, thereby significantly improving the lifespan or reliability of the power module.

Although embodiments of the present disclosure have been shown and described with respect to specific embodiments, it will be apparent to those of ordinary skill in the art that the present disclosure may be variously improved and changed without departing from the technical spirit of the present disclosure provided by the following claims.

What is claimed is:

1. A liquid immersion-cooled power module comprising:
an enclosure;
an insulating liquid filling the enclosure;
a substrate disposed inside the enclosure, the substrate having a plurality of cooling fins in thermal contact with the insulating liquid; and
a chip on the substrate inside the enclosure.

2. The power module of claim 1, wherein the substrate is a plate comprising a metal material.

3. The power module of claim 1, further comprising a support body inside the enclosure and connected to the substrate to fix the substrate inside the enclosure.

4. The power module of claim 1, wherein the plurality of cooling fins are on a first side of the substrate, a second side of the substrate, or on both the first side and the second side of the substrate.

5. The power module of claim 1, wherein the enclosure comprises an inlet and an outlet connecting from an outside to an inside to circulate the insulating liquid.

6. The power module of claim 5, wherein the inlet and the outlet are arranged on a straight line, and the substrate is positioned on the straight line inside the enclosure between the inlet and the outlet.

7. The power module of claim 5, wherein the inlet and the outlet of the enclosure are connected to a flow path through which the insulating liquid flows.

8. The power module of claim 7, further comprising a pump in the flow path to flow the insulating liquid in through the inlet and out through the outlet.

9. The power module of claim 1, further comprising a cooler inside or outside the enclosure and configured to cool the insulating liquid.

10. The power module of claim 9, wherein the substrate is vertically disposed in the enclosure, and the cooler is located on an outer top surface or an inner top surface of the enclosure.

11. A liquid immersion-cooled power module, the power module comprising:
an enclosure;
an insulating liquid filling the enclosure;
a plurality of substrates disposed inside the enclosure, each substrate having a plurality of cooling fins in thermal contact with the insulating liquid;
a connection body electrically connecting the plurality of substrates to each other; and
a plurality of chips on the plurality of substrates.

12. The power module of claim 11, wherein the connection body comprises a plurality of protruding fins configured to exchange heat with the insulating liquid.

13. The power module of claim 12, wherein the connection body is connected to the plurality of chips, and the plurality of protruding fins are provided at a portion of the connection body connected with the chips.

14. The power module of claim 11, wherein each substrate of the plurality of substrates is a plate comprising a metal material.

15. The power module of claim 11, further comprising a support body inside the enclosure and connected to the plurality of substrates to fix the plurality of substrates inside the enclosure.

16. The power module of claim 11, wherein, for each substrate of the plurality of substrates, the plurality of cooling fins are on a first side of the substrate, a second side of the substrate, or on both the first side and the second side of the substrate.

17. The power module of claim 11, wherein the enclosure comprises an inlet and an outlet connecting from an outside to an inside to circulate the insulating liquid.

18. The power module of claim 17, wherein the inlet and the outlet are arranged on a straight line, and the plurality of substrates is positioned on the straight line inside the enclosure between the inlet and the outlet.

19. The power module of claim 17, wherein the inlet and the outlet of the enclosure are connected to a flow path through which the insulating liquid flows, and wherein a pump is provided in the flow path to flow the insulating liquid in through the inlet and out through the outlet.

20. The power module of claim 11, further comprising a cooler inside or outside the enclosure and configured to cool the insulating liquid.
